(19) United States
(12) Patent Application Publication
(10) Pub. No.: US 2025/0203781 A1
(43) Pub. Date: Jun. 19, 2025

(54) RADIO FREQUENCY MODULE AND METHOD FOR MANUFACTURING THE SAME

(71) Applicant: AAC ACOUSTIC TECHNOLOGIES (SHENZHEN) CO., LTD., Shenzhen (CN)

(72) Inventors: Zhiming Zhai, Shenzhen (CN); Chao Wang, Shenzhen (CN); Ying Liu, Shenzhen (CN)

(21) Appl. No.: 18/743,031

(22) Filed: Jun. 13, 2024

Related U.S. Application Data
(63) Continuation of application No. PCT/CN2023/138839, filed on Dec. 14, 2023.

(51) Int. Cl. H05K 1/18; H05K 3/00; H05K 3/10; H05K 3/32

(52) U.S. Cl. CPC H05K 1/185; H05K 3/0044; H05K 3/10; H05K 3/328

(57) ABSTRACT

A method for manufacturing radio frequency module, including: providing initial chip board including substrate and radio frequency modules fixed to the substrate, and the radio frequency module includes components; covering dry film on the initial chip board provided with the radio frequency modules, cavity is formed between the dry film, the components and the substrate; forming first metal layer on the dry film, forming plastic sealing layer on the first metal layer; forming second metal layer on the plastic sealing layer, the second metal layer is electrically connected to the first metal layer; and cutting the initial chip board along boundary between adjacent radio frequency modules to obtain single radio frequency module. The risk of short circuit of the radio frequency module can be effectively reduced, the electromagnetic shielding effect is better, and the production efficiency after electromagnetic shielding treatment is improved.

### TECHNICAL FIELD

The present disclosure belongs to the technical field of electromagnetic shielding, and particularly relates to a method for manufacturing radio frequency module and a radio frequency module.

### BACKGROUND

With the development of science and technology, the requirements on integration level of radio frequency chips becomes higher and higher. For a transmitting radio frequency module, chips with different functions need to be integrated together into a single chip. An electromagnetic interference (EMI) effect is generated between chips with different functions, and the performance of a single chip product is thus affected. The EMI shielding technique is to reduce the electromagnetic interference effect by providing a layer of grounding metal on the outer surface of the chip circuit, so that grounding is achieved by absorbing of the metal.

A chip electromagnetic shielding process in the related art correspondingly cuts chips with different functions after plastic sealing into single chips, and then performs metal layer sputtering on the single chip product. On the one hand, the process conversion efficiency of plastic sealing of individual chips is extremely low, additional conversion fixtures are needed, which increases the cost. On the other hand, when the single chip after plastic sealing is stripped after the metal layer sputtering, the metal wire drawing phenomenon will occur at the bottom of the chip, which easily leads to metal burrs, thus bringing the risk of short circuit that may adversely affect the reliability of the chip.

Therefore, it is necessary to provide a method for manufacturing a radio frequency module with high production efficiency and high reliability.

### SUMMARY

The present disclosure aims to provide a method for manufacturing radio frequency module and a radio frequency module, the radio frequency module with the electromagnetic shielding layer may be manufactured in batches, with high production efficiency and reliability.

The technical solution of the present disclosure is as follows:

A first aspect of the present disclosure provides a method for manufacturing a radio frequency module, including: providing an initial chip board including a substrate and a plurality of radio frequency modules fixed to the substrate, the radio frequency modules including a plurality of components; covering a dry film on a surface of a side of the initial chip board provided with the radio frequency modules, and forming a cavity between the dry film, the components and the substrate; forming a first metal layer on a surface of the dry film, and forming a plastic sealing layer on the first metal layer; forming a second metal layer on a surface of the plastic sealing layer, the second metal layer being electrically connected to the first metal layer; and cutting the initial chip board along a boundary between adjacent radio frequency modules to obtain a single radio frequency module.

As an improvement, prior to the forming the second metal layer on the surface of the plastic sealing layer, the method further includes: cutting the initial chip board to form a groove at a boundary between adjacent radio frequency modules, and a bottom of the groove runs through the first metal layer.

As an improvement, the forming the first metal layer on the surface of the dry film includes: metal vacuum sputtering or electronic paste printing on the surface of the dry film to form the first metal layer.

As an improvement, the forming the second metal layer on the surface of the plastic sealing layer includes: electroplating or metal vacuum sputtering on the surface of the plastic sealing layer to form the second metal layer.

As an improvement, the plurality of components include at least one filter chip and at least one non-filter chip, and a gate region is formed at the first metal layer and the dry film between the non-filter chip and the substrate. The forming a plastic sealing layer on the first metal layer includes: injection molding epoxy resin and breaking the gate region to fill a gap between the non-filter chip, the substrate and the dry film; and continuously injection molding epoxy resin to cover the first metal layer, and forming a plastic sealing layer by curing molding.

As an improvement, a thickness of the first metal layer is 3 μm to 5 μm.

As an improvement, the first metal layer includes at least one metal of steel, copper, aluminum, nickel or silver.

As an improvement, the providing an initial chip board includes: providing a substrate and a plurality of components of a plurality of radio frequency modules; and welding components of the radio frequency modules to corresponding regions of the substrate and cleaning.

As an improvement, the substrate includes a welding region for connecting the components and a non-welding region outside the welding region, and the welding components of the radio frequency modules to corresponding regions of the substrate includes: coating a solder resist on the substrate, to form a solder resist layer in the non-welding region; metalizing surfaces of the components of the radio frequency modules, and adding solder into a reflow furnace to form bumps; and reflow welding the components of the radio frequency modules to the welding region of the substrate.

A second aspect of the present disclosure provides a substrate coated with a solder resist layer and a plurality of components fixed on the substrate, the radio frequency module further includes a dry film covering the substrate and the plurality of components, a first metal layer covering a side of the dry film away from the substrate, a plastic sealing layer covering a side of the first metal layer away from the substrate, and a second metal layer covering an outer surface of the plastic sealing layer. A cavity is formed between the dry film, the components, and the substrate, and the first metal layer is electrically connected to the second metal layer.

The present disclosure has the following beneficial effects:

First, when the first metal layer is formed on the surface of the dry film, since a cavity is formed between the dry film, the component, and the substrate, a metal wire drawing phenomenon does not occur between the component and the metal layer, thereby effectively reducing the risk of short circuit of the radio frequency module that may adversely affect reliability of the module.

Second, a plastic sealing layer is formed on a surface of the first metal layer, a second metal layer is formed on a surface of the plastic sealing layer, and the first metal layer and the second metal layer are electrically connected to form a parallel connection, so that the electromagnetic shielding effect of the radio frequency module is better.

Third, the first metal layer, the plastic sealing layer and the second metal layer are formed on the surface of the initial chip board having the plurality of radio frequency modules and are then cut, so that single radio frequency modules subjected to electromagnetic shielding treatment can be produced in batches, the production cost is reduced, and the production efficiency is improved.

### BRIEF DESCRIPTION OF DRAWINGS

FIG. 1 is a main flow chart of a method for manufacturing a radio frequency module according to an embodiment of the present disclosure;

FIG. 2 is a schematic structural diagram of steps S100 and S200 in FIG. 1 after the completion of the processes;

FIG. 3 is a schematic structural diagram of step S300 in FIG. 1 after completion of the processes;

FIG. 4 is a schematic structural diagram of steps S400 and S500 in FIG. 1 after completion of the processes;

FIG. 5 is a cross-sectional view of a radio frequency module according to an embodiment of the present disclosure.

### DESCRIPTION OF EMBODIMENTS

The present disclosure is further described below with reference to the accompanying drawings and embodiments.

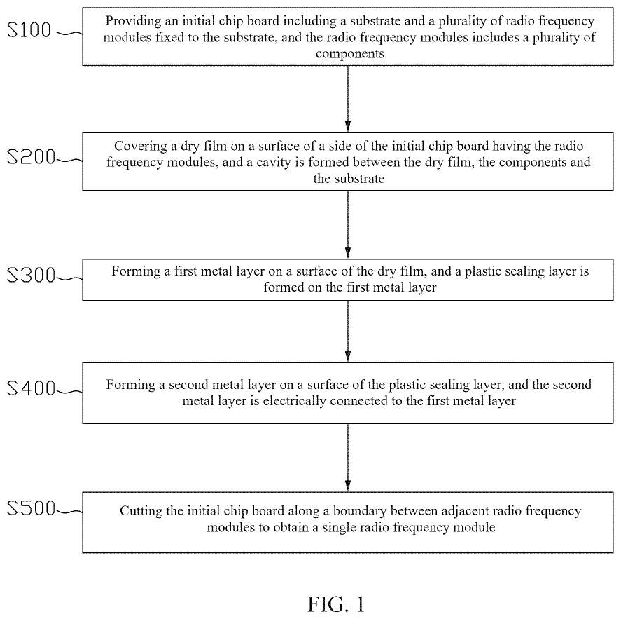

An embodiment of the present disclosure provides a method for manufacturing a radio frequency module, as shown in FIG. 1, including the following steps:
S100: providing an initial chip board including a substrate 120 and a plurality of radio frequency modules fixed to the substrate 120, the radio frequency modules includes a plurality of components 110.
S200, covering a dry film 140 on a surface of a side of the initial chip board having radio frequency module, and forming a cavity between the dry film 140, the component 110 and the substrate 120.
S300, forming a first metal layer 150 on the surface of the dry film 140, and forming a plastic sealing layer 160 on the first metal layer 150.
S400: forming a second metal layer 170 on a surface of the plastic sealing layer 160, the second metal layer 170 is electrically connected to the first metal layer 150.
S500: cutting an initial chip board along a boundary between adjacent radio frequency modules to obtain a single radio frequency module.

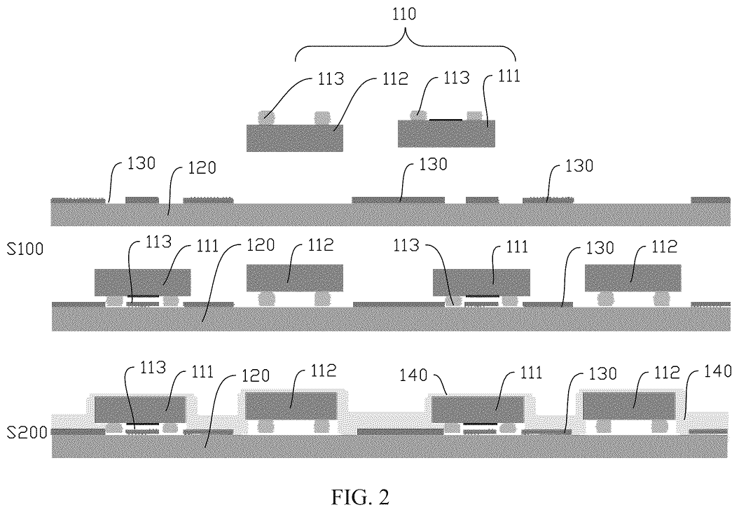

In an embodiment, as shown in FIG. 2, step S100 includes:
S101, providing a substrate 120 and a plurality of components 110 of a plurality of radio frequency modules.

The substrate 120 is a bearing plate of a plurality of sets of components 110 of the radio frequency module, it may be a printed circuit board made of organic resin, or may be a glass substrate 120 or a ceramic substrate 120.

The substrate 120 has a welding region for connecting the components 110 and a non-welding region outside the welding region, and components 110 of each radio frequency module are respectively welded in the corresponding region of the substrate 120.
S102, coating a solder resist on a surface of the substrate 120 to form the solder resist layer 130 in a non-welding region of the substrate 120.

In this step, the surface of the substrate 120 is cleaned to remove dirt and other contaminants, then the surface of the substrate 120 is dried, and the surface of the substrate 120 is coated with a solder resist. For example, the substrate 120 is coated with an ultraviolet curing solder resist, epoxy resin, a part of the solder resist on the surface of the substrate 120 is subjected to light curing to form the solder resist layer 130. Finally, the substrate 120 is immersed in a developer to remove uncured solder resist so as to expose a welding region on the surface of the substrate 120. The solder resist layer is used to form an insulating solder resist layer 130 covering the non-welding region on the surface of the substrate 120, and the solder resist layer 130 prevents the component 110 from being welded to the non-welding region.

In other embodiments, the solder resist may be an ultraviolet curing solder resist, a thermal curing solder resist, a liquid photosensitive solder resist or a dry film 140 solder resist.
S103, metallizing the surfaces of the components 110 of each radio frequency module, and adding solder in a reflow furnace to form bumps 113.

In this step, before the surfaces of the components 110 of the radio frequency modules are metallized, the surfaces of the components 110 are cleaned with glue removed, and the surfaces of the components 110 of the radio frequency modules may be metallized by vacuum sputtering, vacuum evaporation or chemical plating. As an example, the components 110 of each radio frequency module are metalized by vacuum sputtering, the step coverage capability of vacuum sputtering and the adhesion to the substrate are relatively strong, which is suitable for large-scale manufacture of the radio frequency module.

After the surfaces of the components 110 of each radio frequency module are metalized, solder is added to the metalized parts through a reflow furnace to form bumps 113. The solder forming bumps 113 may be made from processes such as electroplating solder bumps 113, printing solder bumps 113, nailhead solder bumps 113 or evaporation solder bumps 113.

The bump 113 may be a solder bump, a copper pillar or a gold bump. As an example, a copper pillar bump is used as the bump 113 in this embodiment, the copper pillar has higher reliability, higher interconnect density, and electrical properties and thermal performance superior to the solder bump. During reflow welding, the copper pillar may maintain its shape in a three-dimensional direction, so that welding of the substrate 120 and each radio frequency module is more precise.
S104, reflow welding the components 110 of each radio frequency module to the substrate 120, and welding the bumps 113 to a region of the substrate 120 where no solder resist layer 130 is formed.

In this step, the component 110 of each radio frequency module is flip-chip interconnected with the substrate 120. The side of the component 110 having the bump 113 is dipped with the soldering flux and attached to the area of the substrate 120 where the solder resist layer 130 is not formed. The attached substrate 120 is placed in the reflow furnace to melt the copper pillar, and the component 110 and the substrate 120 are combined to obtain the initial chip board.
S105, cleaning the welded radio frequency module components 110 and the substrate 120.

In this step, the components 110 and the substrate 120 of each radio frequency module after being welded are cleaned and baked by plasma to remove impurities and pollutants on the components 110 and the substrate 120 of each radio frequency module, which is beneficial to the subsequent processes.

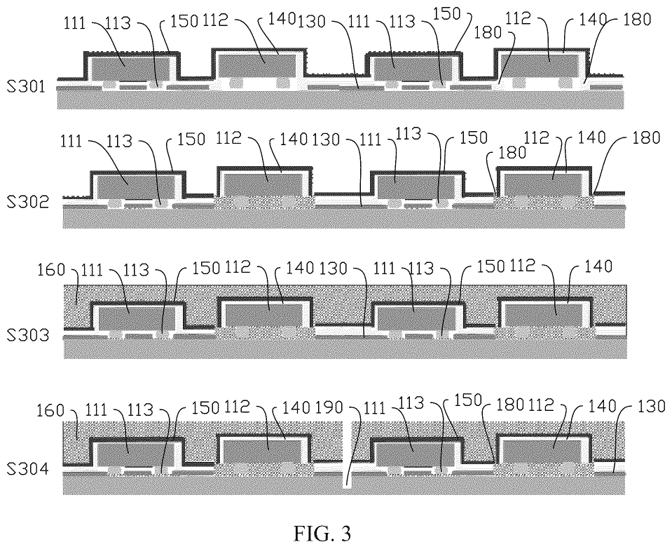

As shown in FIG. 3, step S200: covering a dry film 140 on a surface of a side of the initial chip board having radio frequency module, and forming a cavity between the dry film 140, the component 110 and the substrate 120.

In this embodiment, the surface of the initial chip board having the radio frequency module is covered with a layer of white film, and the white film is used to isolate the filter chip 111 from other metal shielding layers. On one hand, the white film plays a role in protecting functional components of the filter chip 111. On the other hand, the white film isolates the metal shielding layer from the filter chip 111, thereby avoiding metal wire drawing with the edge of the component 110 during vacuum sputtering film stripping, and thereby increasing the reliability of large-scale production of the radio frequency module.

As shown in FIG. 3, in this embodiment, step S300 forming the first metal layer 150 on the surface of the dry film 140 includes:
S301: metal vacuum sputtering or electronic paste printing on the surface of the dry film 140 surface to form the first metal layer 150, the first metal layer 150 includes at least one metal of steel, copper, aluminum, nickel or silver.

As shown in FIG. 3, in this step, vacuum sputtering is used to form the first metal layer 150, the bonding force between the first metal layer 150 and the dry film 140 is strong and not easy to fall off, and the obtained first metal layer 150 has high purity and good quality. In addition, vacuum sputtering has strong film thickness controllability on the first metal layer 150 with high repeatability, and is thus beneficial to large-scale production.

There are a lot of electromagnetic wave interference and infinite radio wave interference between the components 110, and the first metal layer 150 is used to form a metal shielding layer between the plurality of components 110. Compared with the related art in which each component 110 is separately sputtered and film coated, on one hand, the first metal layer 150 formed on the surface of the dry film 140 may electromagnetic shield multiple sets of radio frequency modules in batches, on the other hand, the dry film 140 has formed a cavity between the component 110 and the substrate 120, and the vacuum sputtering film will not contact the metal part on the surface of the component 110, thereby avoiding metal wire drawing with the edge of the component 110 during vacuum sputtering film stripping that may cause metal burrs to be generated at the edge of the component 110, and thus reducing the risk of short circuit of the radio frequency module.

In some embodiments, the target material for vacuum sputtering the first metal layer 150 is selected from stainless steel and copper, the stainless steel and copper are simultaneously used as the sputtering target material with high purity and low impurities, the thin film has better quality and good electrical performance.

Further, the plurality of components 110 include at least one filter chip 111 and at least one non-filter chip 112, the first metal layer 150 and the dry film 140 between the non-filter chip 112 and the substrate 120 have a gate region 180. As shown in FIG. 3, the plastic sealing layer 160 is formed on the first metal layer 150 includes:
S302: injection molding epoxy resin and breaking the gate region 180 to fill the gap between the non-filter chip 112, the substrate 120 and the dry film 140;

As shown in FIG. 3, one side of the filter chip 111 is provided with a functional device having a filtering function. A surface of one side of the filter chip 111 having the functional component is metalized to form a bump 113, the bump 113 connects the filter chip 111 and the substrate 120. A cavity is formed between the functional component and the substrate 120, and the cavity is used to protect the functional component. The non-filter chip 112 may be an electronic component having no filtering function, such as a capacitor, an inductor, or a power amplifier, so that a cavity is not necessarily formed between the non-filter chip and the substrate 120.

The thickness of the first metal layer is 3 μm to 5 μm, so that the first metal layer 150 and the dry film 140 corresponding to the gate region 180 can be broken by adjusting the injection pressure and injecting the epoxy resin at the gate region 180, so that the gap between the non-filter chip 112, the substrate 120 and the dry film is completely filled. The gate region 180 is a local point on the first metal layer 150 and the dry film 140.

The purpose of filling the gap between the non-filter chip 112, the substrate 120 and the dry film 140 is to improve the flip stability of the flip-chip of the non-filter chip 112, the adhesive filling part may disperse the stress concentrated on the non-filter chip 112, so that the capability of the non-filter chip 112 to withstand mechanical vibration is enhanced, the bump 113 may also be prevented from creeping, thereby increasing the strength and rigidity of the connection between the non-filter chip 112 and the substrate 120. Moreover, the non-filter chip 112 is protected from dust and moisture in the environment.
S303: continuing injection molding the epoxy resin to cover the first metal layer 150, and the plastic sealing layer 160 is formed by curing molding.

As shown in FIG. 3, the initial chip board is placed in the plastic sealing mold and completely filled with epoxy resin. The epoxy resin may form a hard protective layer through a curing reaction and has high heat resistance and chemical corrosion, and the plastic sealing layer 160 is used for protecting the internal structure of the chip from being affected by the external environment, and also plays an insulating role between the first metal layer 150 and the second metal layer 170. In addition, different from the plastic sealing process in the related art, the plastic sealing layer 160 in the present disclosure is injection molded and cured on the first metal layer 150 instead of directly injection molded and cured on the surface of the component 110, which reduces the influence of injection molding high voltage on the component 110, and improves the reliability of preparing the radio frequency module, which may also improve the preparation efficiency of the radio frequency module through integral injection molding. In other embodiments, plastic sealing materials such as polyimide, silica gel and organic glass may also be used for injection molding.

In other embodiments, the plastic sealing layer 160 may also be formed by using a process such as integrally pressing an epoxy resin film, which may reduce the process cost, and may also avoid damage to the first metal layer 150 caused by high pressure of injection molding, which play a role in insulating and protecting the first metal layer 150.
S304: semi-cutting the initial chip board to form a groove 190 at a boundary between adjacent radio frequency modules, the bottom of the groove 190 runs through the first metal layer 150.

As shown in FIG. 3, semi-cutting is a process of forming a groove by cutting into the middle of a workpiece. It is appreciate that, the groove 190 may be perpendicular to the substrate 120 and the groove bottom is located inside the substrate 120. In the related art, the semi-cutting technology is used for separating chips, and compared with the related art, the initial chip board uses a semi-cutting process before the second metal layer 170 is formed, and is used for enabling the groove wall of the groove 190 to expose the first metal layer 150, which is beneficial to connect the first metal layer 150 and the second metal layer 170 to form an electromagnetic shielding layer separated from each other inside and outside, and a better electromagnetic shielding effect is achieved.

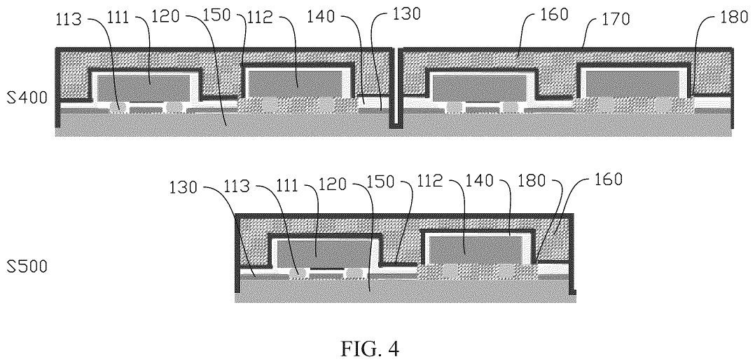

In this embodiment, as shown in FIG. 4, step S400 includes:
S400: electroplating or metal vacuum sputtering on the surface of the plastic sealing layer 160 to form a second metal layer 170, the second metal layer 170 is electrically connected to the first metal layer 150.

The second metal layer 170 is formed on the surface of the plastic sealing layer 160 by electroplating, the second metal layer 170 formed by electroplating is used as an electromagnetic shielding layer. In addition, the second metal layer 170 is located on the outer surface of the radio frequency module, the outer surface of the radio frequency module may be subjected to chemical corrosion, and electroplating the second metal layer 170 may protect the surface of the chip.

The first metal layer 150 serves as an inner shielding layer, the second metal layer 170 serves as an outer shielding layer, the second metal layer 170 and the first metal layer 150 are connected in parallel to effectively shield electromagnetic interference of different frequencies. In addition, the first metal layer 150 may reduce electromagnetic radiation between multiple components 110 of the radio frequency module, and the second metal layer 170 may reduce interference of an external electromagnetic field on the multiple components 110 of the radio frequency module, so that the electromagnetic shielding effect is better.

In some embodiments, the second metal layer 170 sputtered by the vacuum sputtering process includes at least one metal of steel, copper, aluminum, nickel, or silver, and the material of the second metal layer 170 by the electroplating process may be any one of copper, nickel, chromium, gold, zinc, or silver.

As shown in FIG. 4, step 500: cutting the initial chip board to obtain a single radio frequency module.

The cutting process of the semi-cutting process in step S303 is continued to obtain a single radio frequency module, and the method has high efficiency of manufacturing a single radio frequency module.

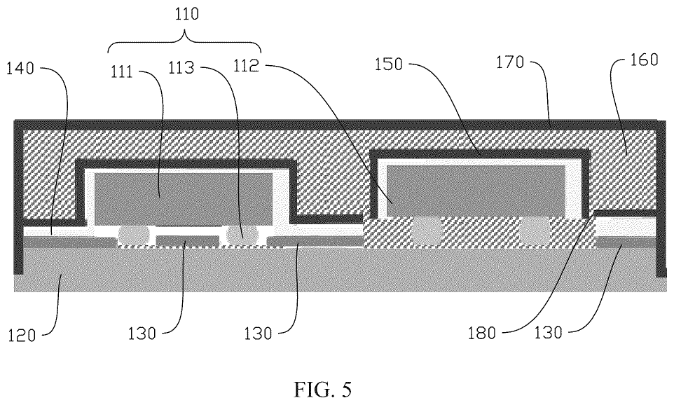

Further, as shown in FIG. 5, a radio frequency module is manufactured by the above method, including a substrate 120 coated with a solder resist layer 130 and a plurality of components 110 fixed on the substrate 120. The radio frequency module further includes a dry film 140 covering the substrate 120 and the plurality of components 110, a first metal layer 150 covering a side of the dry film 140 facing away from the substrate 120, a plastic sealing layer 160 covering a side of the first metal layer 150 away from the substrate 120, and a second metal layer 170 covering an outer surface of the plastic sealing layer 160. A cavity is formed between the dry film 140, the components 110 and the substrate 120, and the first metal layer 150 is electrically connected to the second metal layer 170.

As shown in FIG. 5, a radio frequency module includes a substrate 120 and a solder resist layer 130 coated on a surface of the substrate 120, and the solder resist layer 130 is provided with a plurality of first welding grooves runs through the solder resist layer 130.

The radio frequency module further includes a plurality of components 110 electrically connected to the substrate 120, the plurality of components 110 include at least one filter chip 111 and at least one non-filter chip 112. A plurality of first bumps 113 are provided on a surface of a side of the filter chip 111 close to the substrate 120 at intervals, the plurality of first bumps 113 match with the plurality of first welding grooves in one to one correspondence, and each first bump 113 runs through the corresponding first welding groove and is electrically connected to the substrate 120.

A plurality of second bumps 113 are provided at intervals on a side surface of the non-filter chip 112 close to the substrate 120, the solder resist layer 130 is further provided with a second welding groove runs through the solder resist layer 130, and each second bump 113 runs through the second welding groove and is electrically connected to the substrate 120. The non-filter chip 112, the second welding groove and the substrate 120 are filled with a curing material.

The radio frequency module further includes a dry film 140 covering the plurality of components 110 and covering the surface of the solder resist layer 130, the surface of the dry film 140 is covered with a first metal layer 150. The upper surface of the first metal layer 150 is injection molded to form a plastic sealing layer 160, both the side edge of the radio frequency module and the surface of the plastic sealing layer 160 are covered with a second metal layer 170, and the first metal layer 150 is electrically connected to the second metal layer 170.

In some embodiments, the first metal layer 150 is covered on the dry film 140 by metal vacuum sputtering or electronic paste printing.

In some embodiments, the first metal layer 150 includes at least one metal of steel, copper, aluminum, nickel, or silver.

In some embodiments, the plastic sealing layer 160 is formed by injection molding epoxy resin or pressing molding epoxy resin film on the first metal layer 150.

In some embodiments, the second metal layer 170 covers the plastic sealing layer 160 by electroplating or metal vacuum sputtering.

Compared with a radio frequency module in the related art, a cavity is formed between the dry film 140, the component 110 and the substrate 120, the cavity may protect the component 110 of the radio frequency module. In addition, the component 110 and the first metal layer 150 are isolated, so that the phenomenon of metal wire drawing is avoided, and the risk of short circuit of the radio frequency module is effectively reduced.

The plastic sealing layer 160 between the first metal layer 150 and the second metal layer 170 plays an insulating role, and the first metal layer 150 and the second metal layer 170 are electrically connected to form an electromagnetic shielding layer connected in parallel, so that the radio frequency module achieves a better electromagnetic shielding effect.

The above description only shows some embodiments of the present disclosure, and it should be noted that those skilled in the art can further make improvements without departing from the concept of the present disclosure, but these all fall within the protection scope of the present disclosure.

What is claimed is:

1. A method for manufacturing a radio frequency module, comprising:
providing an initial chip board comprising a substrate and a plurality of radio frequency modules fixed to the substrate, the radio frequency modules comprising a plurality of components;
covering a dry film on a surface of a side of the initial chip board provided with the radio frequency modules, and forming a cavity between the dry film, the components and the substrate;
forming a first metal layer on a surface of the dry film, and forming a plastic sealing layer on the first metal layer;
forming a second metal layer on a surface of the plastic sealing layer, the second metal layer being electrically connected to the first metal layer; and
cutting the initial chip board along a boundary between adjacent radio frequency modules to obtain a single radio frequency module.

2. The method as described in claim 1, wherein prior to the forming the second metal layer on the surface of the plastic sealing layer, the method further comprises:
cutting the initial chip board to form a groove at a boundary between adjacent radio frequency modules, wherein a bottom of the groove runs through the first metal layer.

3. The method as described in claim 1, wherein the forming the first metal layer on the surface of the dry film comprises:
metal vacuum sputtering or electronic paste printing on the surface of the dry film to form the first metal layer.

4. The method as described in claim 1, wherein the forming the second metal layer on the surface of the plastic sealing layer comprises:
electroplating or metal vacuum sputtering on the surface of the plastic sealing layer to form the second metal layer.

5. The method as described in claim 1, wherein the plurality of components comprise at least one filter chip and at least one non-filter chip, and a gate region is formed at the first metal layer and the dry film between the non-filter chip and the substrate;
the forming a plastic sealing layer on the first metal layer comprises:
injection molding epoxy resin and breaking the gate region to fill a gap between the non-filter chip, the substrate and the dry film; and
continuously injection molding epoxy resin to cover the first metal layer, and forming a plastic sealing layer by curing molding.

6. The method as described in claim 1, wherein the first metal layer has a thickness of 3 μm to 5 μm.

7. The method as described in claim 1, wherein the first metal layer comprises at least one metal of steel, copper, aluminum, nickel or silver.

8. The method as described in claim 1, wherein the providing the initial chip board comprises:
providing a substrate and a plurality of components of a plurality of radio frequency modules; and
welding components of the radio frequency modules to corresponding regions of the substrate, and cleaning.

9. The method as described in claim 8, wherein the substrate comprises a welding region for connecting the components and a non-welding region outside the welding region, and the welding components of the radio frequency modules to corresponding regions of the substrate comprises:
coating a solder resist on the substrate, to form a solder resist layer in the non-welding region;
metalizing surfaces of the components of the radio frequency modules, and adding solder into a reflow furnace to form bumps; and
reflow welding the components of the radio frequency modules to the welding region of the substrate.

10. A radio frequency module, comprising a substrate coated with a solder resist layer and a plurality of components fixed on the substrate, wherein the radio frequency module further comprises a dry film covering the substrate and the plurality of components, a first metal layer covering a side of the dry film away from the substrate, a plastic sealing layer covering a side of the first metal layer away from the substrate, and a second metal layer covering an outer surface of the plastic sealing layer, wherein a cavity is formed between the dry film, the components, and the substrate, and the first metal layer is electrically connected to the second metal layer.
